(19) United States
(12) Patent Application Publication
(10) Pub. No.: US 2017/0006732 A1
(43) Pub. Date: Jan. 5, 2017

(54) AIR FLOW MANAGEMENT SYSTEM AND ASSEMBLY

(71) Applicant: Telstra Corporation Limited, Melbourne (AU)

(72) Inventors: Tim McConaghie, Melbourne (AU); Fred Fedrizzi, Melbourne (AU)

(21) Appl. No.: 14/927,975

(22) Filed: Oct. 30, 2015

(30) Foreign Application Priority Data
Jun. 30, 2015 (AU) 2015203654

(51) Int. Cl. H05K 7/20; F24F 13/32; F24F 13/08

(52) U.S. Cl. CPC H05K 7/20127; F24F 13/08; F24F 13/32

(57) ABSTRACT

An air flow management assembly for use with a component of an optical fibre network is disclosed. The component has a face with an exhaust vent through which air from within the component is exhausted. The assembly includes an air deflection panel having a support structure that includes mounts for mounting the air deflection panel on the component. The assembly also includes one or more vanes that are supported by the support structure such that the vanes are spaced from the face, and are each disposed at least partially transversely across the exhaust vent. The vanes are inclined relative to the face, such that air exhausted through the exhaust vent is deflected by the vanes to flow at least partially vertically upward.

### FIELD OF THE INVENTION

The present invention relates to an air flow management system and assembly, which are suitable for use in connection with an optical switch gear assembly and/or within a telecommunications network exchange.

### BACKGROUND

Many modern data and telecommunications networks use fibre-optic network architectures for connecting large portions of the direct-connect network. Network exchanges use optical switch gear assemblies to manage connection and distribution of signals between the network users. Within a large network exchange there may be several hundred switch gear assemblies. It is common to have the assemblies mounted within racks that are arranged side-by-side along corridors within the physical space of the exchange facility. Each rack can receive two or more switch gear assemblies.

As with many components of optical fibre networks, switch gear assemblies produce heat in use, and have an operating temperature range within which the equipment can be expected to perform at the required level. The performance of the equipment can deteriorate when the operating temperature is outside the specified operating temperature range. In sufficiently extreme temperature conditions, equipment can fail catastrophically.

With hundreds of switch gear assemblies and other network components in a physical exchange there is a need to efficiently and effectively manage the heat that is produced by components individually and collectively. Individual components often have vents and extraction fans to move air through the component, which moves heated air out of the unit. The network exchange facilities also have air conditioning systems to extract hot air, and replace the extracted air with cooled air. There can be regions of stagnant air in parts of the network exchange that can be problematic to equipment performance.

It is desired to address the above, to augment the existing cooling systems, and/or at least provide a useful alternative.

### SUMMARY OF THE INVENTION

The present invention provides an air flow management assembly for use with a component of an optical fibre network, the component having a face with an exhaust vent through which air from within the component is exhausted, the assembly including an air deflection panel having:

a support structure that includes mounts for mounting the air deflection panel on the component; and

one or more vanes that are supported by the support structure such that the vanes are spaced from the face, and are each disposed at least partially transversely across the exhaust vent,

wherein the vanes are inclined relative to the face, such that air exhausted through the exhaust vent is deflected by the vanes to flow at least partially vertically upward.

In certain embodiments, the support structure includes a front wall with one or more front openings, and wherein at least some of the vanes are supported by the front wall. Preferably, each of the front openings is immediately below one of the vanes.

Alternatively or additionally, the support structure includes a bottom end portion, and wherein the vanes include one or more lowermost vanes that are supported by the bottom end portion. In some embodiments, the bottom end portion includes a peripheral flange that defines a bottom opening, and the lowermost vanes are supported by the peripheral flange.

Preferably, the lowermost vanes are positioned such that air rising upwardly through the bottom opening is redirected by the lowermost vanes to move away from face of the component.

The support structure can also include a top end portion that has a peripheral flange that surrounds a top opening.

In certain embodiments, the support structure includes side walls that are to be disposed on opposing sides of the exhaust vent.

Preferably, the vanes are formed integrally with the support structure.

The air flow management assembly can further include a first mounting bracket that has a first mounting structure with a first set of mounting holes for securing the first mounting bracket to a component support rack.

In some embodiments, the first mounting bracket further includes a second mounting structure with a second set of mounting holes for securing the first mounting bracket to the face of the component, and the air deflection panel has a slot through which the first mounting bracket passes.

In some alternative embodiments, the first mounting bracket is attached to the air deflection panel. In such embodiments, the first mounting bracket may be integral with the air deflection panel, or first mounting bracket may be connected to the air deflection panel.

The air flow management assembly can further include a second mounting bracket for mounting a rear end of the component to a component support rack. In some embodiments, the second mounting bracket has a first mounting structure with a first set of mounting holes for securing the second mounting bracket to a component support rack, and a second mounting structure with a second set of mounting holes for securing the second mounting bracket to the rear end of the component.

The air flow management assembly can further comprise a front baffle plate that is to be mounted between the component and the component support rack, and adjacent a side wall of the support structure.

The air flow management assembly can further comprise a rear baffle plate that is to be mounted on or adjacent a rear vent formed in the rear wall of the component, the rear baffle plate preventing air discharging rearwardly through the rear vent.

The present invention also provides an air flow management system for use with a component support rack that has two spaced apart side walls between which one or more components of an optical fibre network are mounted, each component having a face with an exhaust vent through which air from within the component is exhausted, the system including, for each of the components, an air flow management assembly as previously described,

wherein the air deflection panel of each assembly is mounted between the face of the respective component and the adjacent side wall of the rack, and wherein the system forms a vertically oriented passageway between the air deflection panel and the adjacent side wall, whereby air passing over the vanes is discharged into the vertically oriented passage.

In embodiments in which two or more components are mounted in the component support rack, the vertically oriented passageways formed between the air deflection panels and the adjacent side wall are vertically aligned.

### BRIEF DESCRIPTION OF THE DRAWINGS

In order that the invention may be more easily understood, embodiments will now be described, by way of example only, with reference to the accompanying drawings, in which:

FIG. 1: is a front view of a typical component support rack with two optical switch gear assemblies, an air flow management system in accordance with a first embodiment of the present invention;

FIG. 2: is a horizontal cross section of the rack, optical switch gear assemblies, and air flow management system, as viewed along the line A-A in FIG. 1;

FIG. 3: is a front view of the rack and optical switch gear assemblies of FIG. 1, with front fascia panels removed from the optical switch gear assemblies;

FIG. 4: is a partial front upper perspective view of one of optical switch gear assemblies its air flow management assembly shown FIG. 1;

FIG. 5: is a front view of the air deflection panel of the air flow management assembly of FIG. 4;

FIG. 6: is a rear view of the air deflection panel of FIG. 5;

FIG. 7: is a top view of the air deflection panel of FIG. 5;

FIG. 8: is a vertical cross section of the air deflection panel, as viewed along the line B-B in FIG. 5;

FIG. 9: is a front view of the left side switch gear mounting bracket of the air flow management assembly of FIG. 1;

FIG. 10: is a right side view of the left side switch gear mounting bracket of FIG. 9;

FIG. 11: is a right side view of the right side switch gear mounting bracket of the air flow management assembly of FIG. 1;

FIG. 12: is a front view of the right side switch gear mounting bracket of FIG. 11;

FIG. 13: is a front upper perspective view of an air flow management assembly in accordance with a second embodiment of the present invention, shown with a schematic optical switch gear assembly;

FIG. 14: is a front lower perspective view of the air flow management assembly and schematic optical switch gear assembly of FIG. 13; and

FIG. 15: is a rear upper perspective view of the air flow management assembly and schematic optical switch gear assembly of FIG. 13.

### DETAILED DESCRIPTION

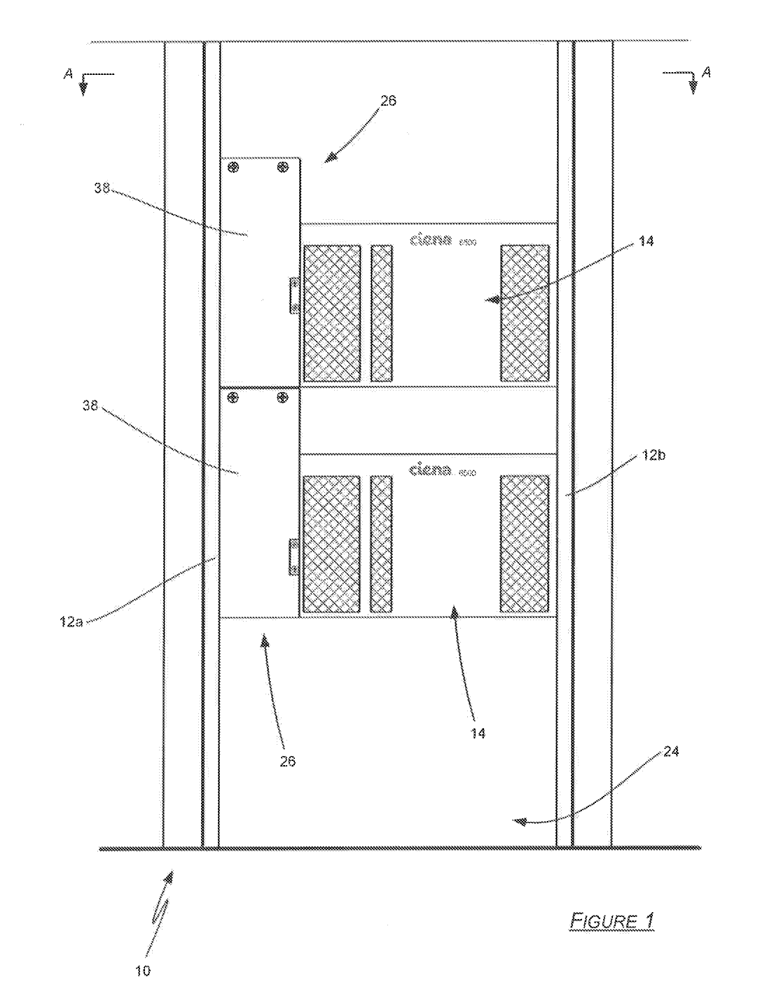

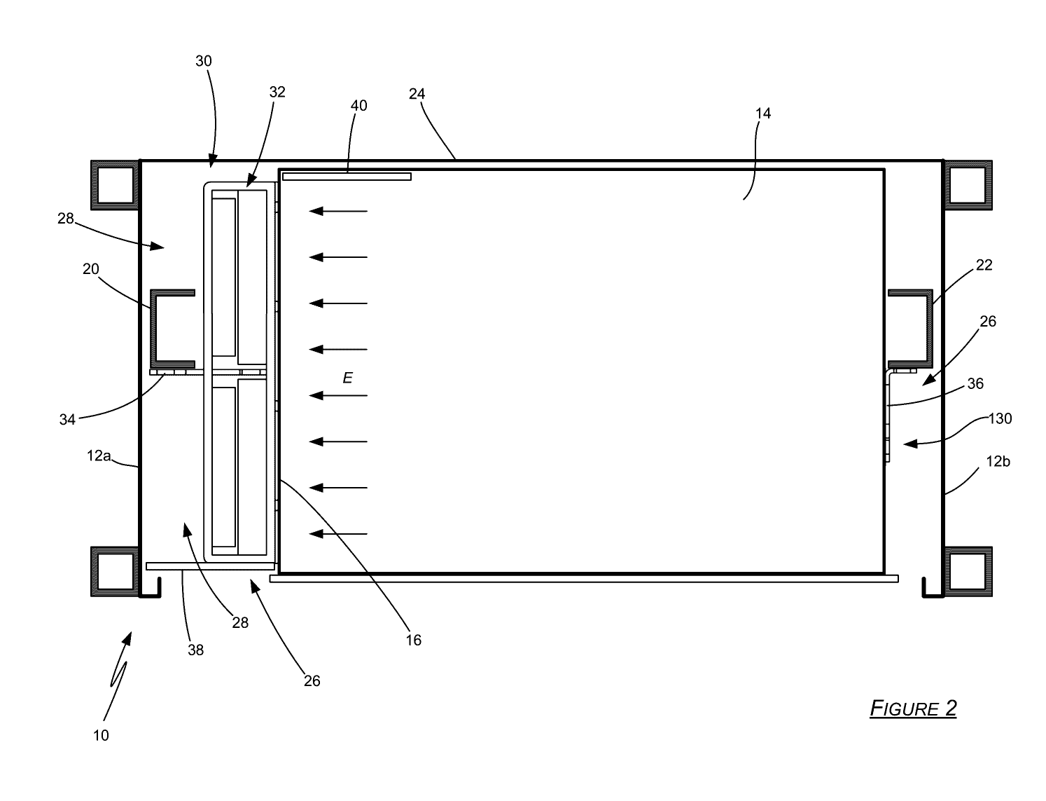

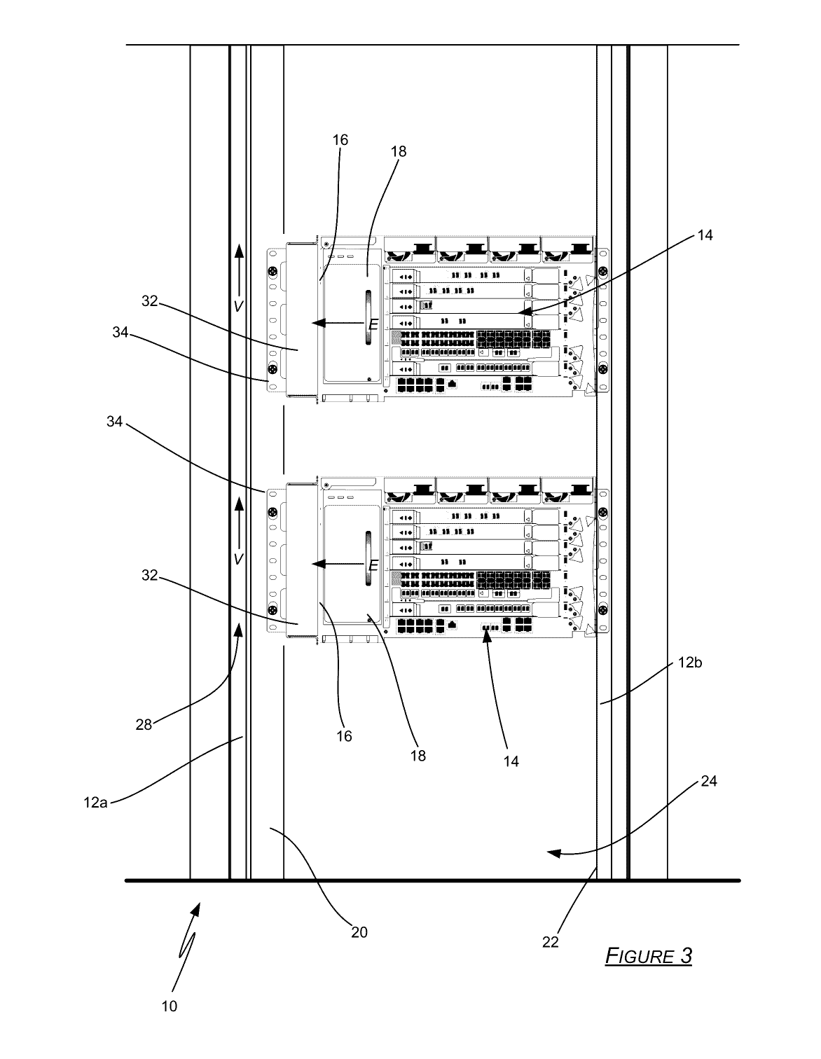

FIGS. 1 to 3 show a component support rack 10 that has two spaced apart side walls 12a, 12b between which two components of an optical fibre network are supported, and a back wall 24. The two side walls 12 and the back wall 24 form a bay within which components are supported. In this example, the components are Ciena 6500-7 Optical Type 2 optical switch gear assemblies 14, which form part of a network exchange. These switch gear assemblies 14 each have a side face 16 with an exhaust vent or grille through which air from the assembly is exhausted. In these assemblies, an extraction fan are housed in a module 18 that is positioned adjacent the face 16, as shown in FIG. 3. The extraction fan operates to draw air across network cards that are mountable within the assembly 14, and exhaust air through the exhaust vent formed in the face 16. The exhaust air is moving horizontally as it leaves the face 16—as indicated by arrows E in FIGS. 2 and 3—and is moving directly towards the adjacent side wall 12a.

An air flow management system 26 in accordance with a first embodiment of the present invention operates passively to redirect the exhaust air to travel vertically upward—as indicated in FIG. 3 by arrows V. The air flow management system 26 includes an air flow management assembly 30 for each of the switch gear assemblies. By redirecting the exhaust air in this manner, the efficiency of moving exhaust air away from the switch gear assemblies 14 is enhanced, which can lower the operating temperature of network cards within the switch gear assemblies 14. This has the advantage of improving the reliability and performance of the switch gear assemblies 14, and thus the network exchange within which the assemblies 14 operate.

In this embodiment, each air flow management assembly 30 includes an air deflection panel 32, a left side mounting bracket 34, a right side mounting bracket 36, and front and rear baffle plates 38, 40. As will be evident from FIGS. 2 and 3, each of the switch gear assemblies 14 is mounted to vertical channel members 20, 22 that form part of the rack 10 structure via the left side and right side mounting brackets 34, 36. Each of the assemblies is spaced from the side walls 12a, 12b. The air deflection panels 32 of each assembly 30 is mounted between the face 16 of the respective switch gear assembly 14, and the adjacent side wall 12a of the rack 10. The air deflection panel 32 has a width that is less than the separation of the face 16 and side wall 12a. Accordingly, the system 26 forms a vertically oriented passageway 28 between the air deflection panel 32 and the adjacent side wall 12a.

The rack 10 of this example supports two switch gear assemblies 14 that each have an airflow management assembly 30, and each of these assemblies 30 forms a vertically oriented passageway 28 with the side wall 12a of the rack 10. The two vertically oriented passageways 28 are aligned vertically. Air exhausted from the two switch gear assemblies 14 is redirected to flow vertically upward through the aligned vertically oriented passageways 28. A chimney effect is created by the vertically oriented passageways 28, such that heated exhaust air rises through the passageways 28 towards the ceiling of the network exchange, where the air can be readily extracted by an air conditioning system.

In each assembly 30, the front baffle plate 38 is mounted beside the air deflection panel 32. The baffle plate 38 inhibits air leaking laterally from the vertically oriented passageway 28, and forwardly of the rack 10. In this embodiment, the front baffle plate 38 is removable to allow access.

A Ciena 6500-7 Optical Type 2 has a rear vent (not shown) in the rear wall behind module 18. The rear baffle plate 40 covers this rear vent to prevent air discharging rearwardly through the rear vent and into the bay formed by rack 10. The rear baffle plate 40 in this example is mounted internally of the component 14, but can alternatively be mounted externally of the component 14.

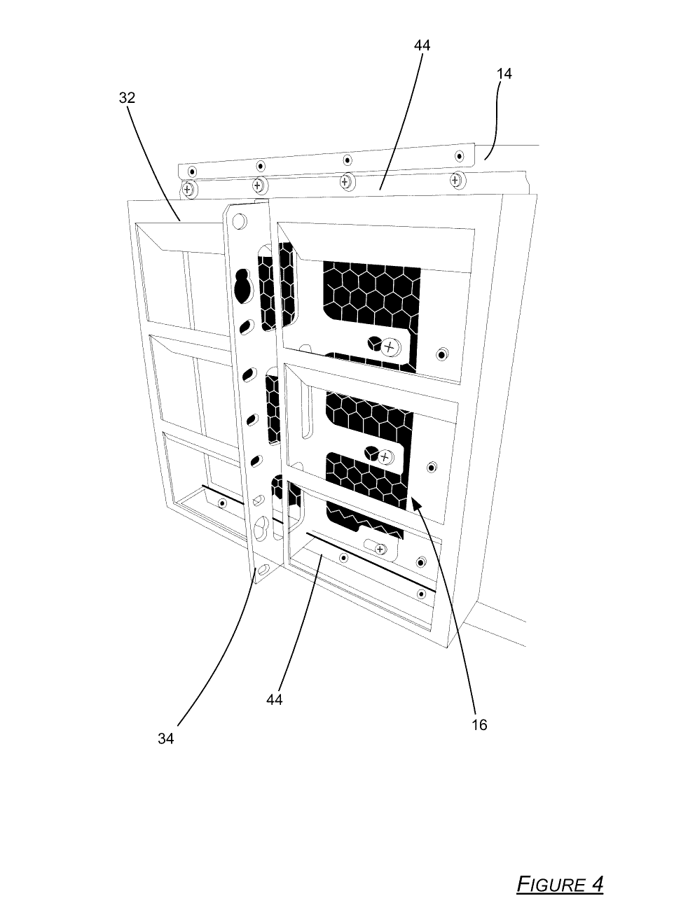

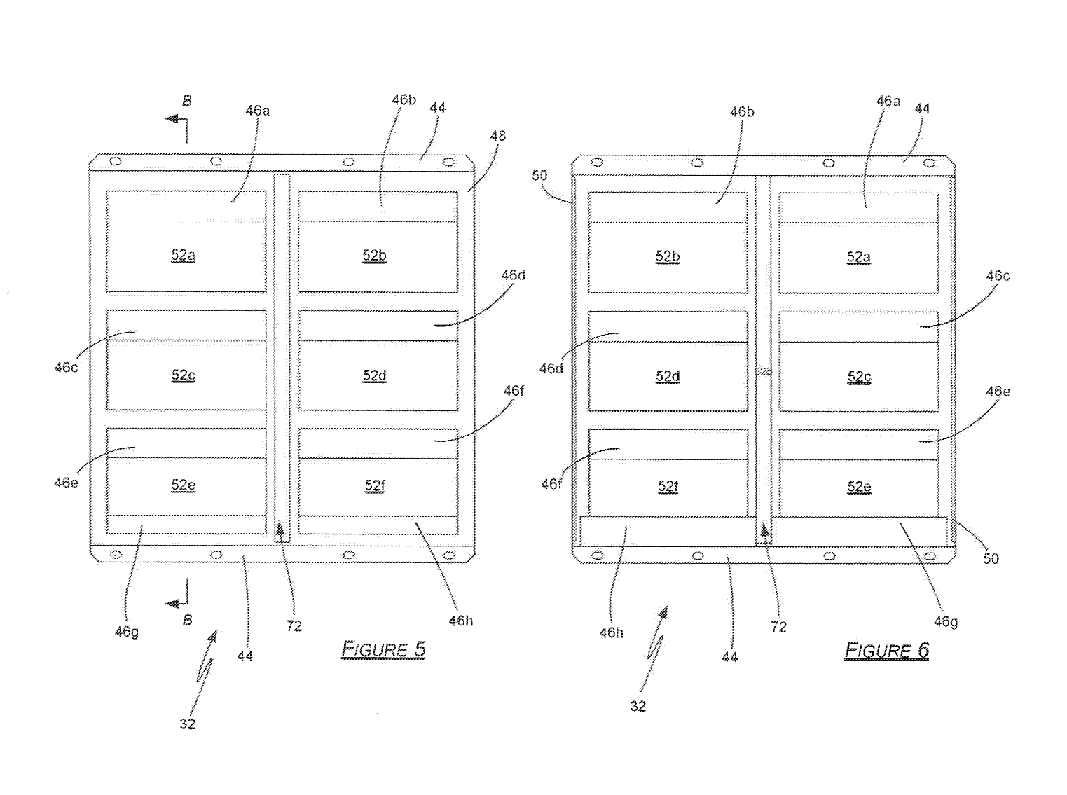

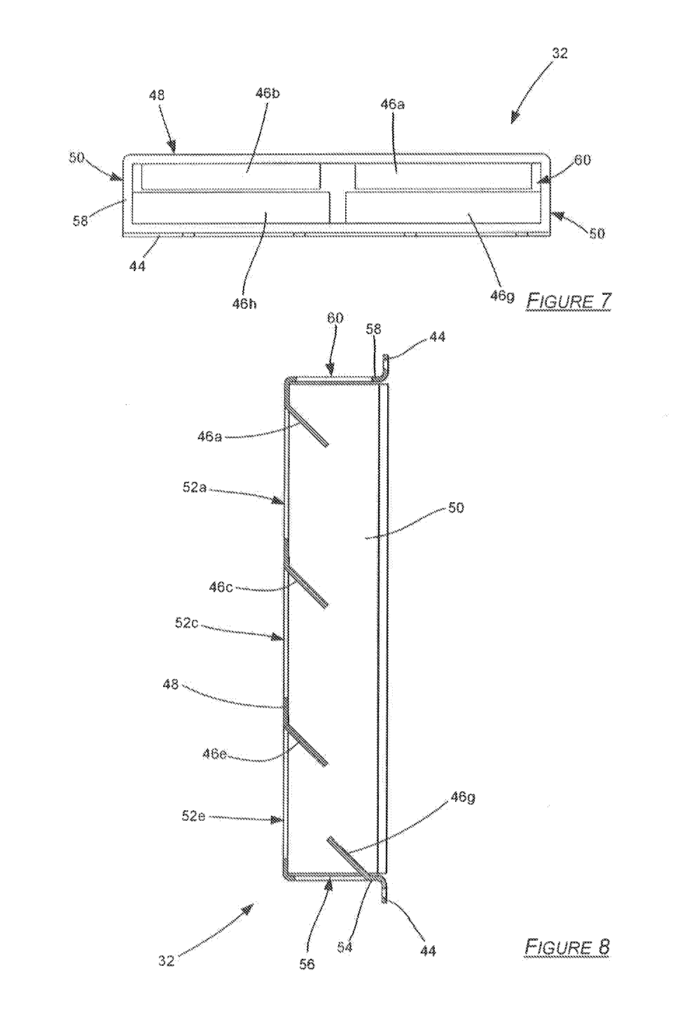

The air deflection panel 32 of this embodiment, which is shown in detail in FIGS. 4 to 8, has a support structure that includes mounts 44 for mounting the air deflection panel 32 on the switch gear assembly 14. The mounts 44 are in the form of a flange with holes through which threaded fasteners can pass to mate with corresponding internally threaded holes in the switch gear assembly 14. However, alternative embodiments may have mounts of different construction.

The air deflection panel 32 also has vanes that are supported by the support structure. In this particular embodiment, the panel 32 has eight vanes 46a, 46b, 46c, 46d, 46e, 46f, 46g, 46h (hereinafter referred to collectively as “vanes 46”). The vanes 46 are spaced from the face 16, and are disposed across the exhaust vent formed in the face 16.

Further, in this embodiment the vanes 46 of this embodiment are arranged in two columns, each consisting of four of the vanes 46.

As will be most apparent from FIGS. 4 and 8, the vanes 46 are inclined relative to the face 16, such that air exhausted through the exhaust vent is deflected by the vanes 46 to flow at least partially vertically upward. In this embodiment, the vanes 46 are set at an angle of approximately 45° to vertical.

The support structure includes a front wall 48, a bottom end portion, a top end portion, and side walls 50 that are to be disposed on opposing sides of the exhaust vent when the air deflection panel 32 is mounted on the face 16 of the switch gear assembly 14. The side walls 50 serve to constrain movement of air that has been expelled from the switch gear assembly 14.

The front wall 48 has six front openings 52a, 52b, 52c, 52d, 52e, 52f. The air deflection panel 32 is formed such that each of the six front openings 52 is immediately below one of the eight vanes 46.

In the illustrated embodiment, the lowermost vanes 46g, 46h are supported within the bottom end portion. As shown most clearly in FIG. 8, the bottom end portion includes a peripheral flange 54 that defines a bottom opening 56. Each of the lowermost pair of vanes 46g, 46h is connected to the peripheral flange 54, and is remote from the front wall 48. Thus, a portion of any warm air rising into the air deflection panel 32 through the bottom opening 56 is directed away from the face 16, and thus towards the front wall 48 and the openings 52.

The top end portion also has a peripheral flange 58 that surrounds a top opening 60. Warm air within the air deflection panel 32 that is above the vanes 46 can exit the panel 32 via the top opening 60.

In this example, the vanes 46 are formed integrally with the support structure. In particular, vanes 46a, 46b, 46c, 46d, 46e, 46f are integral with the front wall 48. The lowermost pair of vanes 46g, 46h are integral with the peripheral flange 54 of the bottom end portion.

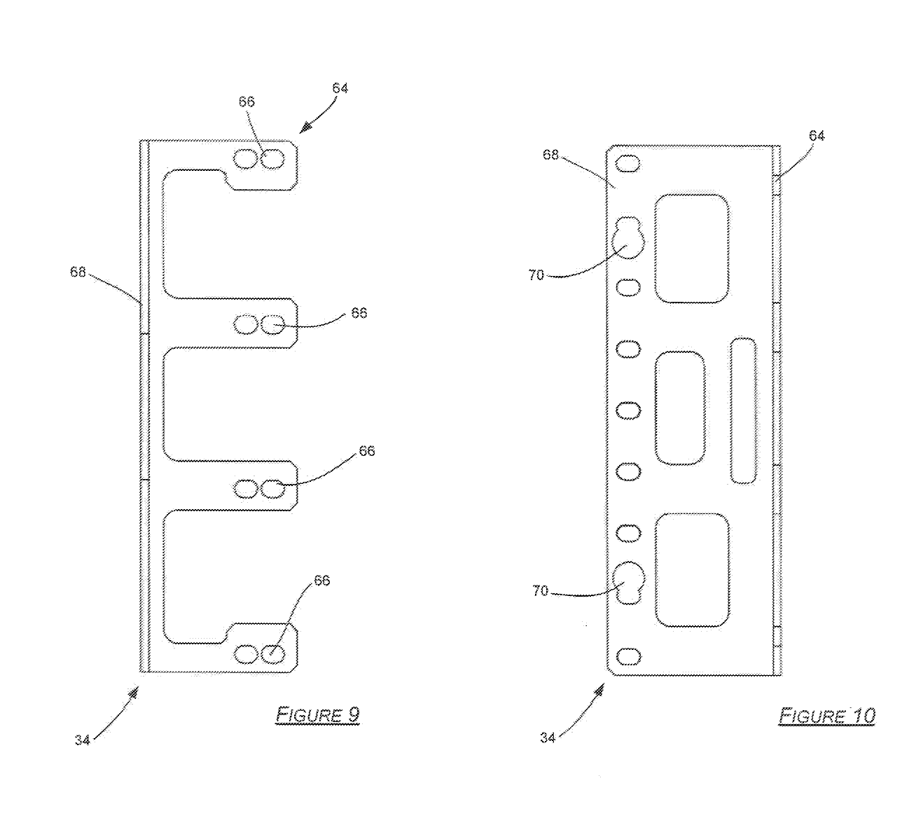

The left side mounting bracket 34 of this embodiment is shown in FIGS. 9 and 10. The left side mounting bracket 34 has a first mounting structure 64 with a first set of mounting holes 66, and a second mounting structure 68 with a second set of mounting holes 70. When a component—such as switch gear assembly 14—is mounted within a rack 10 using the air flow management assembly 30, the first mounting structure 64 is connected to the component via fasteners that pass through the first set of mounting holes 66 and secure into corresponding holes in the component. Further, the second mounting structure 68 is connected to the vertical channel member 20 of the rack 10 via fasteners that pass through the second set of mounting holes 70 and secure into corresponding holes in the vertical channel member 20. In this example, the first mounting structure 64 has four spaced apart arms, with the mounting holes 70 formed in the outer ends of the arms. With this shape, restriction to discharge of air through the exhaust vent on the face 16 by the first mounting structure 64 is minimized.

As shown in FIGS. 4 to 6, the air deflection panel 32 has an elongate slot 72 that is configured to enable the left side mounting bracket to pass through the air deflection panel 32. Thus, when the left side mounting bracket 34 and air deflection panel 32 are assembled on a component, the second mounting structure 68 projects beyond the front wall 48, with the second set of mounting holes 70 in a position required to connect to the vertical channel member 20.

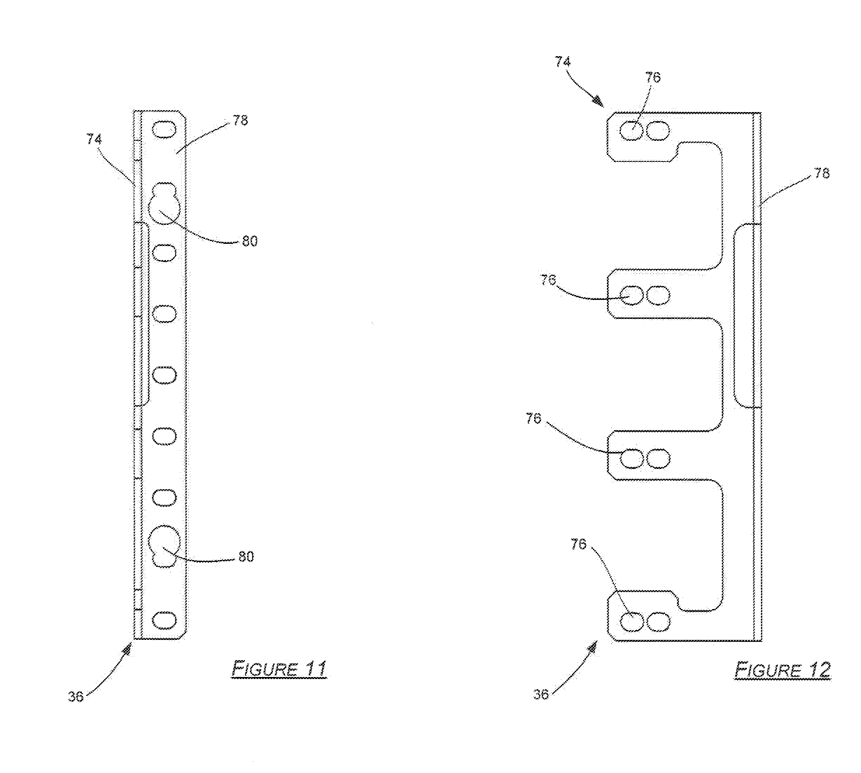

The right side mounting bracket 36 of this embodiment is shown in FIGS. 11 and 12. The right side mounting bracket 36 has a first mounting structure 74 with a first set of mounting holes 76, and a second mounting structure 78 with a second set of mounting holes 80. When a component—such as switch gear assembly 14—is mounted within a rack 10 using the air flow management assembly 30, the first mounting structure 74 is connected to the component via fasteners that pass through the first set of mounting holes 76 and secure into corresponding holes in the component. Further, the second mounting structure 78 is connected to the vertical channel member 22 of the rack 10 via fasteners that pass through the second set of mounting holes 80 and secure into corresponding holes in the vertical channel member 20. The first mounting structure 74 has four spaced apart arms, with the mounting holes 80 formed in the outer ends of the arms. In some components such as the Ciena 6500-7, the right side face (that is, the face at the opposite end of the assembly 14 to face 16) has a vent or grille to allow air movement into/out of the assembly 14. The shape of the first mounting structure 74 minimizes restriction to air movement through the grille on the right side face.

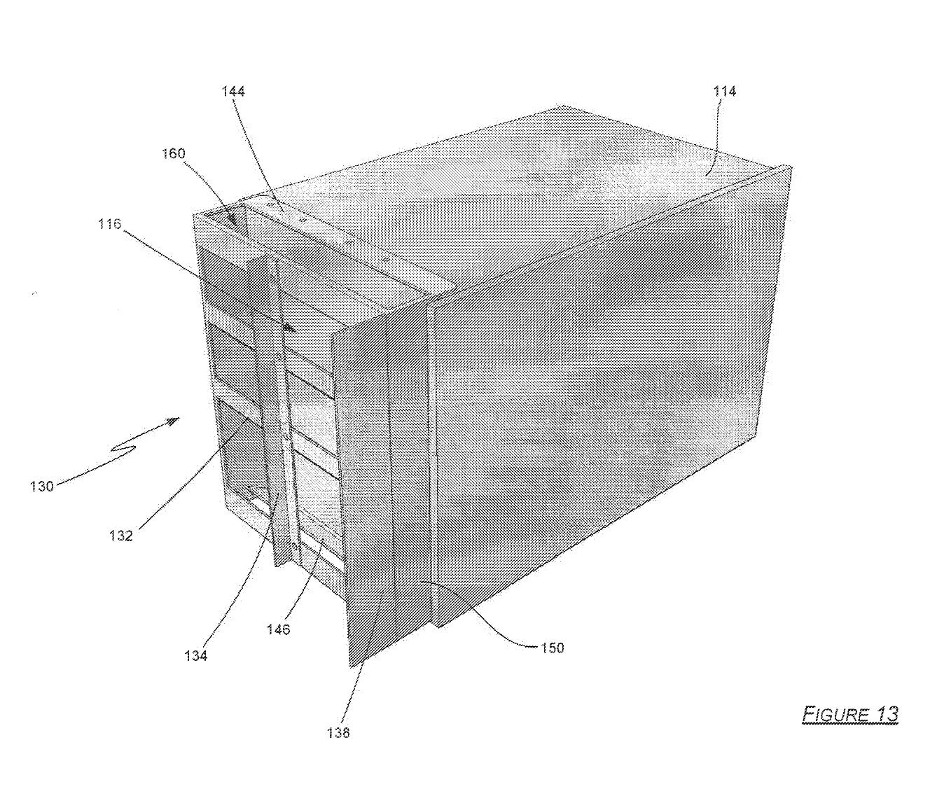

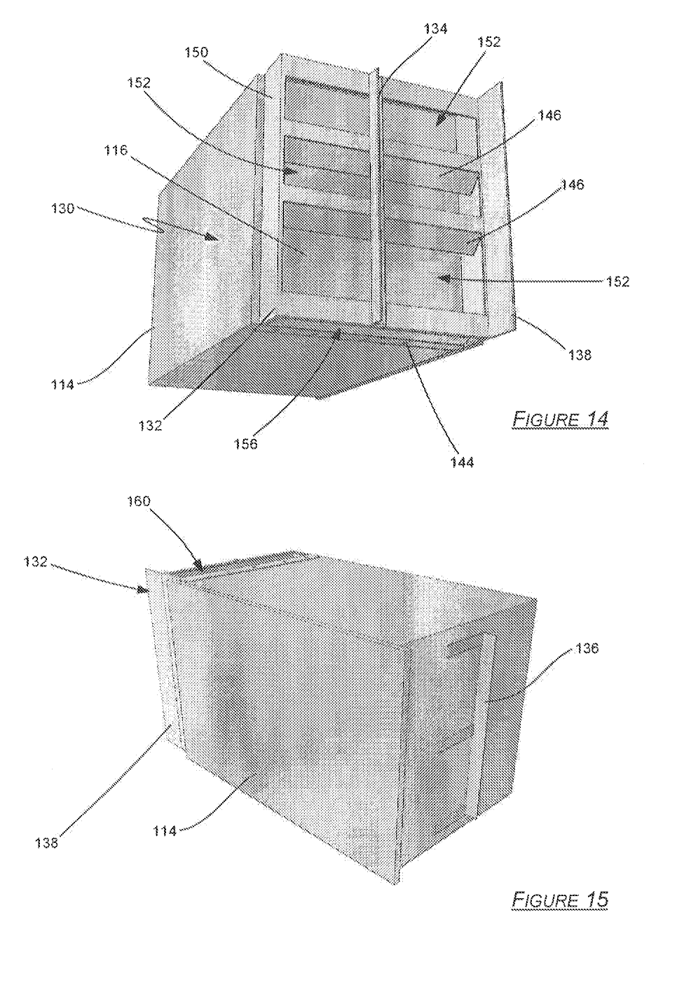

FIGS. 13 to 15 show an air flow management assembly 130 according to a second embodiment of the present invention. The assembly 130 is shown mounted to a schematically illustrated optical switch gear assembly C of an optical fibre network.

The air flow management assembly 130 is substantially similar to the air flow management assembly 30 of FIGS. 1 to 12. In FIGS. 13 to 15, the features of the air flow management assembly 130 that are substantially similar to those of the air flow management assembly 30 have the same reference numeral with the prefix “1”.

In contrast to the construction of the air flow management assembly 30, in this second embodiment, the left side mounting bracket 134 is connected to the front wall 148 of the air deflection panel 132. The connection can be, for example, made using fasteners (such as bolts, rivets, etc.), or using welds. As will be appreciated, in this embodiment, the weight of the assembly 114 is carried through the air deflection panel 132. The mounts 144 of the air deflection panel 132 have a different configuration to provide a stiffer connection. Notably, the air deflection panel 132 has four vanes 146.

In addition, in this embodiment, the front baffle plate 138 is permanently attached to the air deflection panel 132.

1. An air flow management assembly for use with a component of an optical fibre network, the component having a face with an exhaust vent through which air from within the component is exhausted, the assembly including an air deflection panel having:
a support structure that includes mounts for mounting the air deflection panel on the component; and
one or more vanes that are supported by the support structure such that the vanes are spaced from the face, and are each disposed at least partially transversely across the exhaust vent,
wherein the vanes are inclined relative to the face, such that air exhausted through the exhaust vent is deflected by the vanes to flow at least partially vertically upward.

2. An air flow management assembly according to claim 1, wherein the support structure includes a front wall with one or more front openings, and wherein at least some of the vanes are supported by the front wall.

3. An air flow management assembly according to claim 2, wherein each of the front openings is immediately below one of the vanes.

4. An air flow management assembly according to claim 2, wherein the support structure includes a bottom end portion, and wherein the vanes include one or more lowermost vanes that are supported by the bottom end portion.

5. An air flow management assembly according to claim 4, wherein the bottom end portion includes a peripheral flange that defines a bottom opening, and the lowermost vanes are supported by the peripheral flange.

6. An air flow management assembly according to claim 5, wherein the lowermost vanes are positioned such that air rising upwardly through the bottom opening is redirected by the lowermost vanes to move away from face of the component.

7. An air flow management assembly according to claim 1, wherein the support structure further include a top end portion that has a peripheral flange that surrounds a top opening.

8. An air flow management assembly according to claim 1, wherein the support structure includes side walls that are to be disposed on opposing sides of the exhaust vent.

9. An air flow management assembly according to claim 1, wherein the vanes are formed integrally with the support structure.

10. An air flow management assembly according to claim 1, further including a first mounting bracket that has a first mounting structure with a first set of mounting holes for securing the first mounting bracket to a component support rack.

11. An air flow management assembly according to claim 10, wherein the first mounting bracket further includes a second mounting structure with a second set of mounting holes for securing the first mounting bracket to the face of the component, and the air deflection panel has a slot through which the first mounting bracket passes.

12. An air flow management assembly according to claim 10, wherein the first mounting bracket is attached to the air deflection panel.

13. An air flow management assembly according to claim 12, wherein the first mounting bracket is integral with the air deflection panel, or wherein first mounting bracket is connected to the air deflection panel.

14. An air flow management assembly according to claim 1, further including a second mounting bracket for mounting a rear end of the component to a component support rack.

15. An air flow management assembly according to claim 14, wherein the second mounting bracket has a first mounting structure with a first set of mounting holes for securing the second mounting bracket to a component support rack, and a second mounting structure with a second set of mounting holes for securing the second mounting bracket to the rear end of the component.

16. An air flow management assembly according to claim 1, further including a front baffle plate that is to be mounted between the component and the component support rack, and adjacent a side wall of the support structure.

17. An air flow management assembly according to claim 1, further including a rear baffle plate that is to be mounted on or adjacent a rear vent formed in the rear wall of the component, the rear baffle plate preventing air discharging rearwardly through the rear vent.

18. An air flow management system for use with a component support rack that has two spaced apart side walls between which one or more components of an optical fibre network are mounted, each component having a face with an exhaust vent through which air from within the component is exhausted, the system including, for each of the components, an air flow management assembly including an air deflection assembly having a supporting structure including mounts for mounting the air deflection panel on the component, the air deflection assembly further having one or more vanes supported by the support structure such that the vanes are spaced form the face and are each disposed at least partially transversely across the exhaust vent, wherein the vanes are inclined relative to the face, such that air exhausted through the exhaust vent is deflected by the vanes to flow at least partially vertically upward,
wherein the air deflection panel of each assembly is mounted between the face of the respective component and the adjacent side wall of the rack, and wherein the system forms a vertically oriented passageway between the air deflection panel and the adjacent side wall, whereby air passing over the vanes is discharged into the vertically oriented passage.

19. An air flow management system according to claim 18, wherein the system has two or more components mounted in the component support rack, and wherein the vertically oriented passageways formed between the air deflection panels and the adjacent side wall are vertically aligned.
